(19) United States
(12) Patent Application Publication
(10) Pub. No.: US 2006/0220710 A1
(43) Pub. Date: Oct. 5, 2006

(54) Delay locked loop device

(76) Inventor: Alessandro Minzoni, Morrisville, NC (US)

Correspondence Address: EDELL, SHAPIRO & FINNAN, LLC, 1901 RESEARCH BLVD., SUITE 400, ROCKVILLE, MD, 20850, US

(21) Appl. No.: 11/391,696

(22) Filed: Mar. 29, 2006

Related U.S. Application Data
(63) Continuation of application No. PCT/DE04/02166, filed on Sep. 29, 2004.

(30) Foreign Application Priority Data
Sep. 29, 2003 (DE) DE 103 45 236.2

(51) Int. Cl. H03L 7/00

(52) U.S. Cl. 327/153

(57) ABSTRACT

A delay device, with a controllable delay time, has three circuit parts. The delay device is connected in series between an input connection for receiving an input clock signal and an output connection for outputting an output clock signal. The delay time is set based on a phase difference between the input clock signal and the output clock signal. The first circuit part reduces the frequency of the input clock signal and forwards a clock signal with a reduced frequency. The second circuit part delays the signal and forwards it to the third circuit part which uses the modified clock signal to generate the output clock signal which has a frequency matching that of the input clock signal. Since a low-frequency clock signal is processed in the second circuit part, problems relating to a signal change in a high-frequency input clock signal in a delay chain are avoided.

### CROSS REFERENCE TO RELATED APPLICATIONS

This application is a continuation of PCT/DE2004/002166, filed Sep. 24, 2004, and titled “Delay Control Loop,” which claims priority to German Application No. DE 103 45 236.2, filed on Sep. 29, 2003, and titled “Delay Locked Loop,” the entire contents of which are hereby incorporated by reference.

### FIELD OF THE INVENTION

The present invention relates to a delay locked loop device.

### BACKGROUND

Delay locked loop devices are provided, for example, in clock-controlled integrated circuits in order to set an output clock signal from the delay locked loop device in terms of the phase difference between said output clock signal and an input clock signal. Delay locked loop devices (DLLs) are used, in particular, in synchronously operated dynamic semiconductor memories, especially in so-called DDR SDRAMs (Double Data Rate Synchronous Dynamic Random Access Memories) in this case. A clock signal which is supplied on the input side is delayed with the aid of a delay locked loop device, using a control loop, in such a manner that an output-side clock signal has a prescribed phase angle.

A delay locked loop device or a DLL circuit is used in DDR SDRAMs to provide data signals (which are to be written or read out) in synchronism with a clock signal which is supplied on the input side, to be precise both on the rising and on the falling edge of this clock signal. The phase locked loop takes into account the internal signal propagation times of the supplied clock and, in particular, a time delay in receiver circuits for receiving signals and a time delay in output drivers for providing output signals. When reading data signals from the memory, the output driver is supplied, by the DLL circuit, with a clock signal, which has been appropriately set and has been delayed with respect to the input clock signal, in order to emit the output data (which are to be driven) in synchronism with the clock signal which is present on the external data bus.

In order to be able to operate the DDR SDRAM in a wide operating frequency range, it is necessary for the DLL circuit to be able to be operated in a wide operating frequency range which should be able to be varied in a flexible manner, in particular. A low operating frequency requires a long controllable delay time of the delay device contained in the control loop, for which a comparatively long delay chain for delaying by more than one clock period is generally required. On the other hand, a high resolution of the delay chain is required for high operating frequencies in order to align the output clock signal with the input clock signal as effectively as possible even at high operating frequencies.

At high clock signal frequencies, particularly at frequencies of higher than 500 MHz, the problem also arises that the signal waveform of an output clock signal can be changed, with respect to the signal waveform of the input clock signal, by the delay chain in the delay device of a DLL circuit. FIG. 1A shows an embodiment of a known delay chain of a delay locked loop device with an associated signal diagram for an input clock signal (which is to be delayed) at different places in the delay chain. The delay chain 10 shown in FIG. 1A has inverter stages 1-1 to 1-n which are connected in series, an input clock signal having a square-wave signal profile being applied to the input connection IN of the inverter stage 1-1. A respective capacitance 2-1 to 2-n is connected to the respective connecting node between the inverter stages 1-1 to 1-n via respective switching transistors 3-1 to 3-n. In this case, the transistors 3-1 to 3-n can be controlled by a control voltage vn. An output clock signal can be taken from the output connection OT of the inverter stage 1-n. The delay chain 10 which has been designed in this manner exhibits a low-pass filter behavior with respect to an input clock signal at a high frequency, with the result that the clock signal at the connecting nodes K1 and K2 and at the output connection OT has the signal profile shown in FIG. 1B. Such a change in the signal profile of the input clock signal at the output connection OT means that it is scarcely still possible to generate a suitable output clock signal at the output of a DLL circuit at high frequencies of an input clock signal.

The document US 2002/0027967 A1 describes a delay locked loop device which comprises a phase detector for detecting a phase difference between an external clock signal and an internal clock signal, a control unit and a variable delay unit. The control circuit controls the variable delay unit, on the basis of the phase difference (detected by the phase detector) between the external clock signal and the internal clock signal, in such a manner that the internal clock signal is synchronized with the external clock signal. The variable delay unit comprises a first group of delay cells, which can be connected to a first output line via controllable switches, and second delay cells, which can be connected to a second output line via further controllable switches. The delay cells are driven by the external clock signal. In the case of a high-frequency external clock signal, delay cells in the first group are activated and are connected to the first output line. In the case of a low-frequency external clock signal, the delay cells in the first group are activated together with the delay cells in the second group, and the first output line for generating the internal clock signal is connected to the second output line via a controllable switch. Since, in the high-frequency operating case, the second output line is separated from the first output line by the controllable switch, the load of the second output line is reduced. This makes it possible to ensure stable operation of the delay locked loop device when it is driven with a high-frequency external clock signal.

The document DE 100 65 376 C1 describes a delay circuit having an adjustable delay. The delay circuit comprises a first block and a downstream second block which each have a chain of delay elements. Each block is assigned a group of switches which can be used to select output-side taps of the delay elements using switches in order to be able to select a desired delay time. In order to simultaneously drive the switch which is connected to the output-side delay element of the first block and the switch which is connected to the input-side delay element of the second block, the control inputs of said switches are connected to one another. This makes it possible, even at high clock rates, to avoid interference pulses from clock signals which can be applied to the input side of the delay elements. The delay circuit described is therefore particularly suited to use in delay locked loop devices in DDR memory chips.

### SUMMARY

The present invention provides a delay locked loop device that can be operated in a wide operating frequency range and provides a suitable output clock signal even at high operating frequencies.

The delay locked loop device according to the invention comprises a delay device including a controllable delay time and is connected in series between the input connection that receives the input clock signal which is to be delayed and the output connection that taps off an output clock signal which has been delayed.

The delay device according to the invention includes a first circuit part, a second circuit part which is connected downstream of the first circuit part and a third circuit part which is connected downstream of the second circuit part. A control device provides a control signal—which can be supplied to the delay device—on the basis of a phase difference between the clock signal which is to be delayed and the clock signal which has been delayed. The first circuit part receives the input clock signal, reduces the frequency of the input clock signal and outputs a clock signal which is at a reduced frequency to the second circuit part. The latter forwards the clock signal which is at a reduced frequency to the third circuit part in such a manner that said clock signal has been delayed by a controllable delay time. The third circuit part uses the delayed clock signal which is at a reduced frequency to generate the output clock signal which is at the frequency of the input clock signal.

According to the invention, the frequency of the input clock signal which is to be delayed is thus reduced in the delay device of the delay locked loop device. In the second circuit part, the low-frequency clock signal is supplied, in particular, to a delay chain whose delay time can be controlled. In the third circuit part, the clock signal which is at a reduced frequency and has been delayed in the delay chain is used to reconstruct the output clock signal which is again at the frequency of the input clock signal. Since a clock signal which is at a reduced frequency is processed in the delay chain of the second circuit part, it is possible to avoid the problems relating to the signal change in the input clock signal described in the introduction with reference to FIG. 1. At the same time, the invention has the further advantage that a delay chain of a conventional type can be used for the second circuit part and that the delay locked loop device can nevertheless be operated at high operating frequencies. In this case, it is advantageous that the value of the delay time to be set in the delay locked loop device can be left unchanged with respect to the previous solution. Furthermore, the lower operating frequency range can also be retained, with the result that, overall, the delay locked loop device according to the invention can be operated in a wide operating frequency range. In particular, the invention makes it possible to process an operating frequency of an input clock signal of up to 1.4 GHz.

According to one preferred embodiment of the invention, the input connection receives the input clock signal which is to be delayed and an input clock signal which is complementary to the latter. The first circuit part uses the input clock signal to generate the clock signal which is at a reduced frequency and uses the complementary input clock signal to generate a complementary clock signal which is at a reduced frequency. The second circuit part has two delay chains, one of the delay chains forwarding the clock signal which is at a reduced frequency, and the other delay chain forwarding the complementary clock signal which is at a reduced frequency, to the third circuit part with a respective controllable delay time. The third circuit part uses the delayed clock signal and the delayed complementary clock signal which is at a reduced frequency to generate the output clock signal.

In one development, the third circuit part is designed in such a manner that the rising edges of the output clock signal are generated from the rising and falling edges of the delayed clock signal which is at a reduced frequency. The falling edges of the output clock signal are correspondingly generated from the rising and falling edges of the delayed complementary clock signal which is at a reduced frequency. In this case, it is particularly advantageous if the second circuit part is configured such that the delay times are approximately the same for the clock signal which is at a reduced frequency and the complementary clock signal which is at a reduced frequency. To this end, use is preferably made of a delay chain having a symmetrical switching behavior as regards rising and falling edges of a clock signal, with the result that the rising and falling edges of the clock signal which is at a reduced frequency and of the complementary clock signal which is at a reduced frequency are delayed to approximately the same extent.

The above and still further features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIGS. 1A and 1B show an embodiment of a known delay chain of a delay locked loop device with an associated signal diagram for a clock signal (which is to be delayed) at different places in the delay chain.

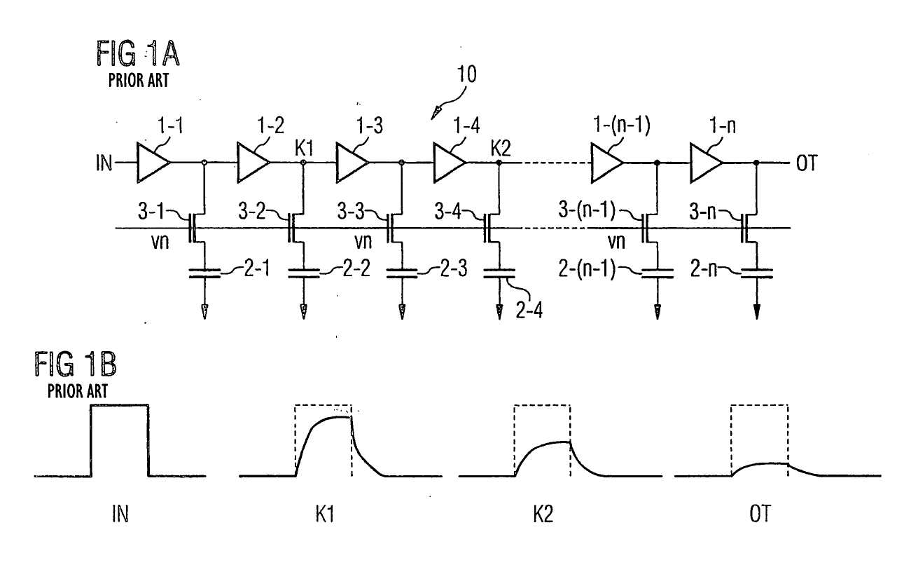

FIG. 2 shows an embodiment of a delay locked loop device according to the invention.

FIGS. 3A and 3B show an embodiment of a first circuit part of a delay device of the delay locked loop device according to the invention with an associated signal diagram.

FIGS. 4 to 7 show embodiments of delay chains for a delay device of the delay locked loop device according to the invention.

FIGS. 8A and 8B shows a first embodiment of a third circuit part of a delay device of the delay locked loop device according to the invention with an associated signal diagram.

FIG. 9 shows a signal diagram for signals in one embodiment of a delay locked loop device according to the invention.

FIG. 10 shows a second embodiment of a third circuit part of a delay device of the delay locked loop device according to the invention.

FIG. 11 shows a signal diagram for signals in another embodiment of a delay locked loop device according to the invention.

### DETAILED DESCRIPTION

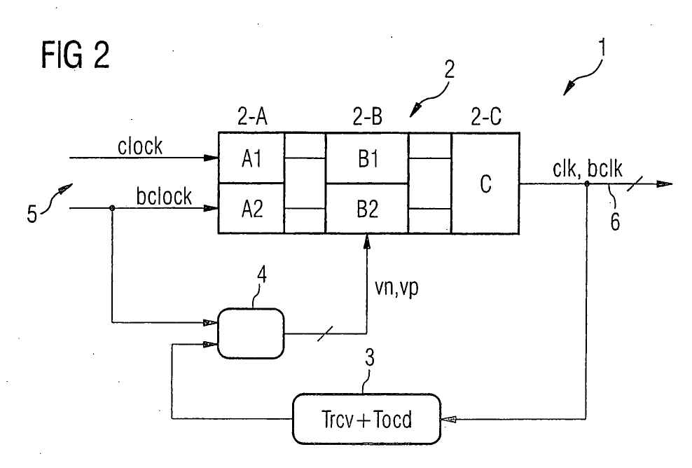

FIG. 2 shows an embodiment of a delay locked loop device according to the invention. The delay locked loop device 1 illustrated in FIG. 2 has an input connection 5 which is supplied with an input clock signal clock which is to be delayed. In the embodiment shown in FIG. 2, an input clock signal bclock which is complementary to the input clock signal clock is also supplied to the input connection 5. An output clock signal clk which has been delayed with respect to the input clock signal clock is provided, via a delay device 2, at the output connection 6 of the delay locked loop device. An output clock signal bclk which is complementary to the complementary input clock signal bclock and has been delayed is correspondingly provided at the output connection 6. The output clock signal clk and the complementary output clock signal bclk are fed back, via a delay element 3 having a constant delay time, to a control device 4 having a phase detector. The delay times Trcv of signal receiver circuits and Tocd of output driver circuits are taken into account in the delay element 3. Here, the phase detector compares this fed-back output signal with the complementary input clock signal bclock and emits a control signal vn, vp, which represents the phase difference, to the delay device 2. In this case, the control signal vn, vp is set on the basis of a phase difference between the input clock signal clock and bclock which is to be delayed and the output clock signal clk and bclk which has been delayed. Delay times in the delay device 2 can be set in this manner. Delay times in the delay device 2 are appropriately adjusted on the basis of the magnitude and sign of the phase difference. Regulation is designed to adjust the phase difference at the phase detector as far as possible to zero.

The delay device 2 shown in FIG. 2 has three different circuit parts 2-A, 2-B and 2-C which are indicated in the form of blocks in FIG. 2 and whose structure will be explained in even more detail below. The first circuit part 2-A is, for its part, subdivided into two circuit blocks A1, A2, and the second circuit part 2-B is correspondingly subdivided into individual circuit blocks B1, B2. In this case, the circuit block B1 is connected downstream of the circuit block A1, and the circuit block B2 is connected downstream of the circuit block A2. The third circuit part 2-C is connected downstream of the second circuit part 2-B and has the circuit block C. The circuit block A1 of the first circuit part 2-A receives the input clock signal clock, and the circuit block A2 of the first circuit part 2-A receives the input clock signal bclock which is complementary to said input clock signal clock. The circuit block A1 uses the input clock signal clock to generate a clock signal which is at a reduced frequency at its output, and the circuit block A2 uses the complementary input clock signal bclock to generate a complementary clock signal which is at a reduced frequency at its output. The circuit blocks B1 and B2 of the second circuit part 2-B forward these clock signals which are at a reduced frequency, with a respective controllable delay time, to the third circuit part 2-C whose circuit block C uses the delayed clock signal and the complementary clock signal which are at a reduced frequency to generate the output clock signals clk, bclk which are at the frequency of the input clock signals clock and bclock.

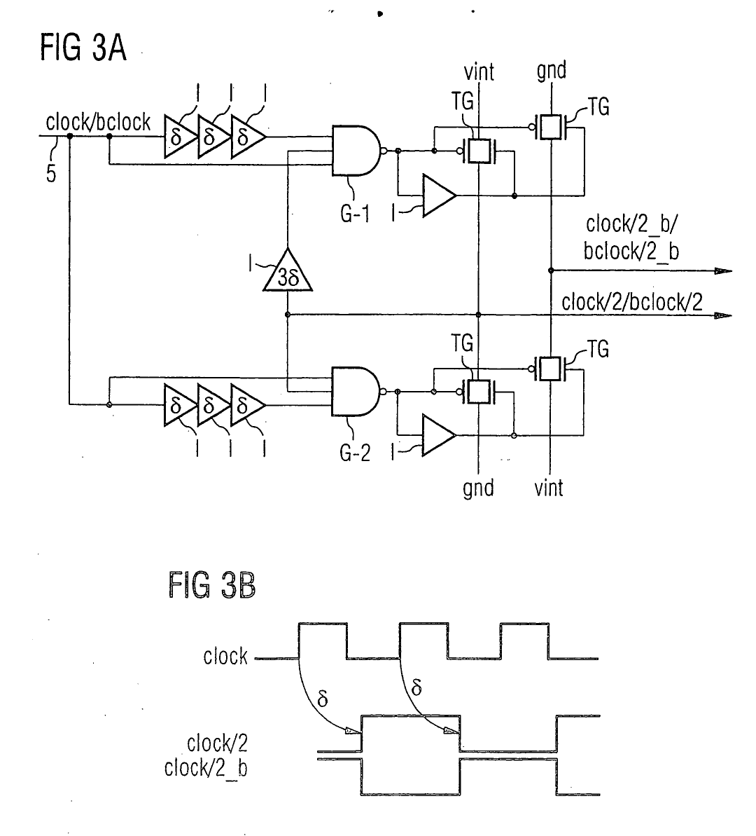

FIG. 3 shows an embodiment of a first circuit part (and its circuit blocks A1, A2) of a delay locked loop device as shown in FIG. 2 with an associated signal diagram. In this case, the circuit blocks A1 and A2 are designed in the same manner, as illustrated using FIG. 3A. They each have a connection of inverter stages I with a respective delay δ, NAND gates G-1, G-2 and transfer gates TG in the manner indicated in FIG. 3A. The inverter stage I for coupling the gates G-2 and G-1 has a delay 3δ. The voltages vint and gnd which respectively denote an internal positive supply potential and a reference voltage of the delay locked loop device are applied to the transfer gates TG.

The circuit block A1 (cf. also in conjunction with FIG. 2) receives the input clock signal clock and generates the clock signal clock/2 which is at a reduced frequency at one output. According to the embodiment shown in FIG. 3A, the circuit block A1 also generates a clock signal clock/2_{—}b which is complementary to the clock signal clock/2. The circuit block A2 receives the complementary input clock signal bclock and generates, at one of the outputs, the complementary clock signal bclock/2 which is at a reduced frequency and, at the other of the outputs, a complementary clock signal bclock/2_{—}b which is at a reduced frequency and is complementary to said complementary clock signal bclock/2. An exemplary signal profile for the clock signals clock, clock/2 and clock/2_{—}b is shown in the signal diagram of FIG. 3B. In the present exemplary embodiment, the clock signals clock/2 and clock/2_{—}b are each at half the frequency of the clock signal clock. The edges are each delayed by the delay time δ relative to corresponding edges of the signal clock.

The frequency of the input clock signal is thus reduced, halved in the present case, in the first circuit part, the time information of the rising edges of the input clock signal being transformed into a rising and a falling edge of the clock signal which is at a reduced frequency.

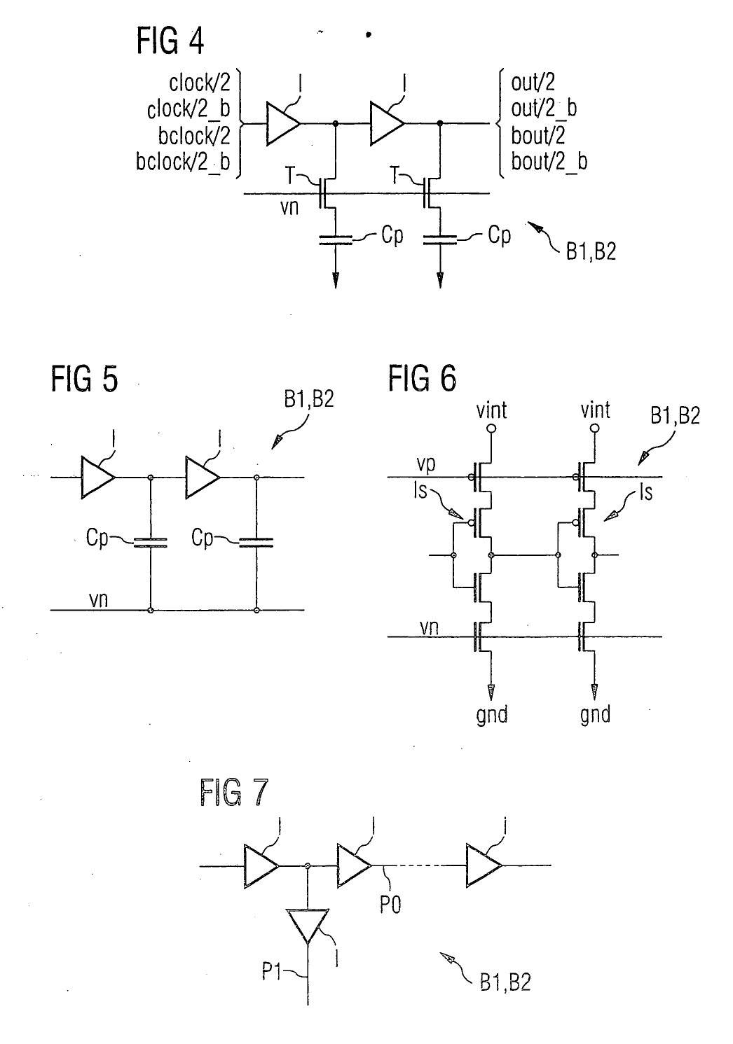

FIGS. 4 to 7 illustrate, in more detail, respective embodiments of the fundamental form of delay chains for use in a delay device of the delay locked loop device shown in FIG. 2. In this case, one delay chain may be used to implement each of the circuit blocks B1, B2.

The delay chain shown in FIG. 4 has inverter stages I which are connected in series, a capacitance Cp being connected to respective connecting nodes between the inverter stages I. A first connection of the respective capacitance Cp is connected to the respective connecting node via a controllable transistor T, the transistor T being able to be controlled by the control signal vn from the control device 4. If the delay chain shown in FIG. 4 is provided in the circuit block B1, the left-hand inverter stage I receives the clock signal clock/2 which is at a reduced frequency. The right-hand inverter I correspondingly outputs the delayed clock signal out/2 which is at a reduced frequency at its output. Since the circuit blocks A1 and A2 according to the embodiment shown in FIG. 3 each forward two output signals to the circuit part 2-B, the latter has four delay chains which each receive one of the clock signals and output a respective delayed clock signal. In addition to the delayed clock signal out/2 which is at a reduced frequency, the delayed clock signal out/2_{—}b which is at a reduced frequency and is complementary to the latter, the delayed complementary clock signal bout/2 and the delayed complementary clock signal bout/2_{—}b which is at a reduced frequency and is complementary to the latter are correspondingly available at the outputs of the second circuit part 2-B.

FIG. 5 illustrates another embodiment of a delay chain for the second circuit part 2-B of the delay locked loop device shown in FIG. 2. The delay chain shown in FIG. 5 again has inverter stages I which are connected in series, a respective capacitance Cp being connected to respective connecting nodes between the inverter stages. A first connection of the respective capacitance Cp is connected to the respective connecting node, and a second connection of the capacitance is connected to a potential connection, the potential vn at the potential connection being able to be controlled by the control device 4.

FIG. 6 illustrates another embodiment of a delay chain having two controllable inverter stages Is which are connected in series. The inverter stages Is can be controlled, in terms of their switching speed, via the control potentials vn and vp and are connected between the supply potentials vint and gnd.

FIG. 7 illustrates another embodiment of a delay chain having a branched arrangement of inverter stages I. In this case, the delay time can be controlled by connecting and disconnecting inverter stages in different branches. By way of example, an inverter stage I in the signal path P0 is connected for a first delay time, and, in contrast, the inverter stage I in the signal path P1 is connected for a second delay time.

The embodiments of a delay chain as shown in FIGS. 4 to 6 have the feature in common that they are of symmetrical design as regards rising and falling edges of a clock signal which is to be delayed, with the result that the rising and falling edges of a clock signal which is to be delayed are delayed to approximately the same extent. In contrast, the delay chain according to the embodiment shown in FIG. 7 is of asymmetrical design.

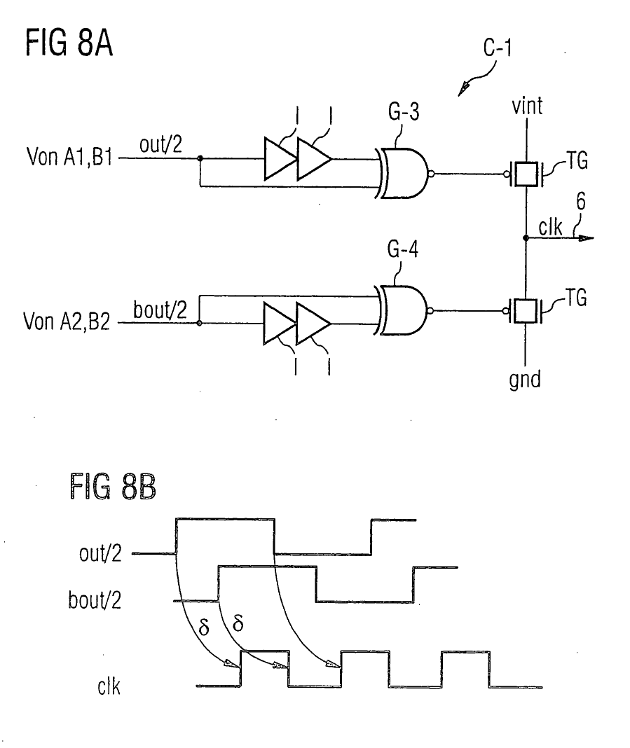

FIG. 8 shows a first embodiment of a third circuit part of a delay device of the delay locked loop device shown in FIG. 2 with an associated signal diagram. In this case, only the delayed clock signal out/2 which is at a reduced frequency and the delayed complementary clock signal bout/2 which is at a reduced frequency are used to generate the output clock signal clk. The circuit block C-1 shown in FIG. 8A has a connection of inverter stages I, EXNOR gates G-3, G-4 and transfer gates TG in the manner indicated in FIG. 8A.

It becomes clear, from the signal diagram from FIG. 8B, that the circuit block C-1 for implementing the third circuit part 2-C shown in FIG. 2 generates the rising edges of the output clock signal clk from the rising and falling edges of the delayed clock signal out/2 which is at a reduced frequency. The falling edges of the output clock signal clk are correspondingly generated from the rising and falling edges of the delayed complementary clock signal bout/2 which is at a reduced frequency. The output clock signal clk is at the frequency of the input clock signal clock, that is to say is at twice the frequency of the clock signals out/2 and bout/2 in the present example.

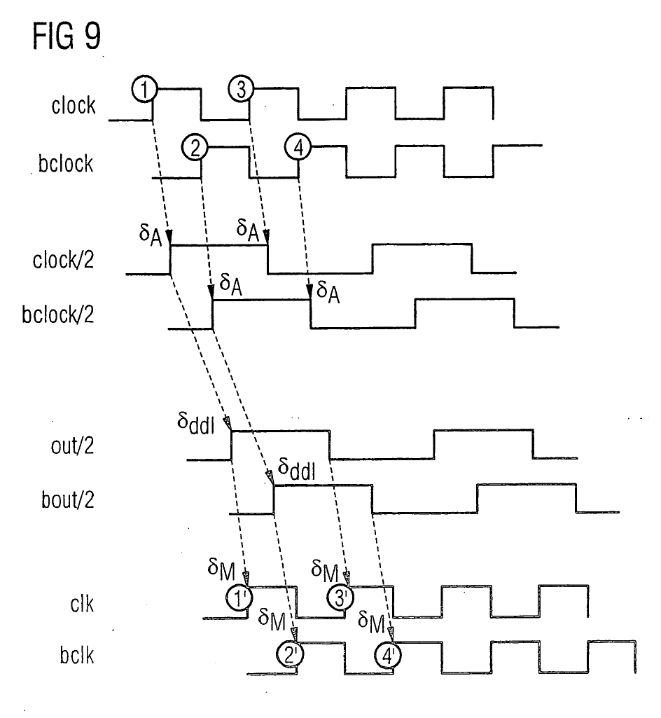

FIG. 9 shows a signal diagram for signals in accordance with an embodiment of a delay locked loop device whose delay device has only two delay chains in the second circuit part. A circuit block A1 generates the clock signal clock/2 which is at a reduced frequency, and a circuit block A2 generates the complementary clock signal bclock/2 which is at a reduced frequency (cf. also FIG. 3). The clock signal out/2 which is at a reduced frequency and has been delayed with respect to clock/2 can be tapped off at a first delay chain, and the complementary clock signal bout/2 which is at a reduced frequency and has been delayed with respect to bclock/2 can be tapped off at a second delay chain. In this case, the delay chains have the delay time δdll. The clock signals clock/2 and bclock/2 are generated with the delay time δA. The rising edges of the output clock signal clk are generated from the rising and falling edges of the delayed clock signal out/2 which is at a reduced frequency, and the falling edges of the output clock signal clk (and the rising edges of the complementary output clock signal bclk) are generated from the rising and falling edges of the delayed complementary clock signal bout/2 which is at a reduced frequency. This is respectively effected with the delay time δM.

According to this embodiment, the circuit part 2-C may be of comparatively simple design (cf. FIG. 8) but assuming that the rising and falling edges of the clock signals are delayed to approximately the same extent in the delay chain. In total, clock signals clk, bclk whose rising edges at times (1′) to (4′) have been delayed by the same delay time with respect to the rising edges of the clock signals clock, bclock at times (1) to (4) are obtained. The delay δA between the rising edge of the input clock signal and the rising or falling edge of the clock signal which is at a reduced frequency is set to the same fixed value and does not change with the operating frequency.

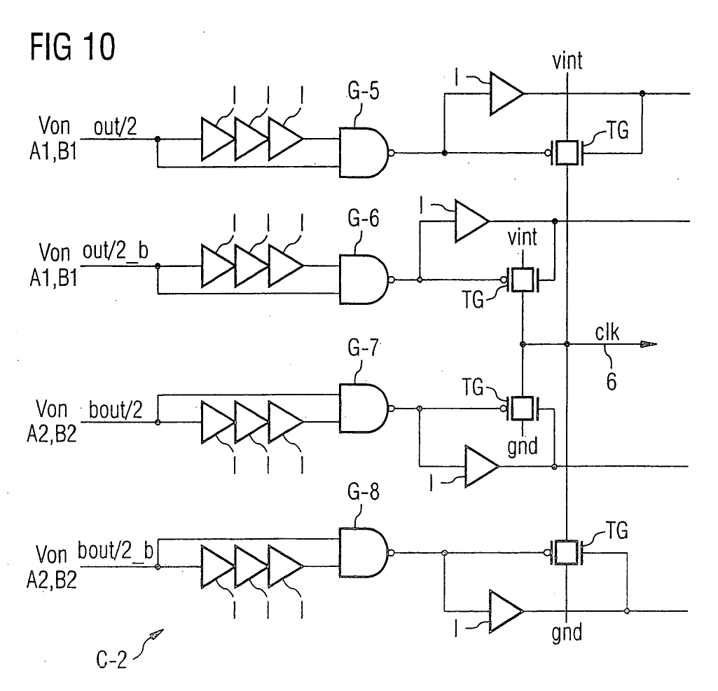

FIG. 10 shows a second embodiment of a third circuit part of a delay device of the delay locked loop device shown in FIG. 2. In this case, all of the clock signals which are output from the first circuit part 2-A (cf. circuit blocks A1, A2 shown in FIG. 3) are used to reconstruct the output clock signal clk. In this exemplary embodiment, the second circuit part 2-B has four delay chains which respectively output the delayed clock signals out/2, out/2_{—}b, bout/2 and bout/2_{—}b. The circuit block C-2 of the third circuit part has the connection of inverter stages I, NAND gates G-5 to G-8 and transfer gates TG indicated in FIG. 10.

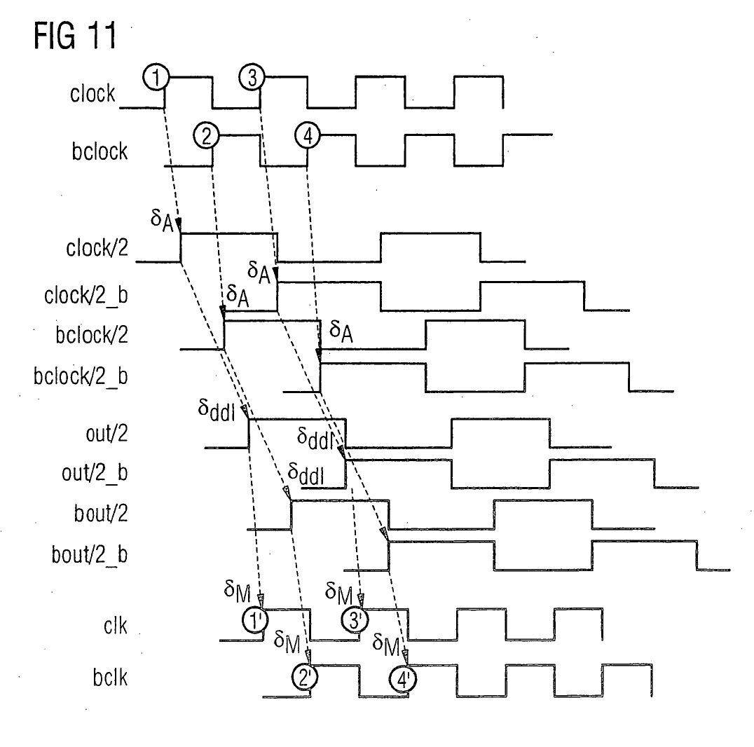

FIG. 11 shows an associated signal diagram for signals in a corresponding embodiment of a delay locked loop device shown in FIG. 2. The circuit block A1 of the first circuit part 2-A uses the input clock signal clock to generate the clock signal clock/2 and a clock signal clock/2_{—}b which is at a reduced frequency and is complementary to the latter. The circuit block A2 of the first circuit part 2-A uses the complementary input clock signal bclock to generate the complementary clock signal bclock/2 which is at a reduced frequency and a complementary clock signal bclock/2_{—}b which is at a reduced frequency and is complementary to the latter. A respective one of the delay chains of the second circuit part 2-B (each of the circuit blocks B1, B2 has two delay chains) forwards one of these signals to the third circuit part 2-C. The latter is, in particular, in the form of the circuit block C-2 shown in FIG. 10 and generates the rising edges of the output clock signal clk from the rising edges of the delayed clock signal out/2 and the rising edges of the delayed complementary clock signal out/2_{—}b. The falling edges of the output clock signal clk (and the rising edges of the complementary output clock signal bclk) are correspondingly generated from the rising edges of the delayed complementary clock signal bout/2 and the rising edges of the delayed complementary clock signal bout/2_{—}b which is complementary. This embodiment has the advantage that only the rising edges of clock signals which are output from the respective delay chain are decisive for reconstructing the output clock signal. A delay chain which is asymmetrical as regards rising and falling edges may correspondingly be used.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SYMBOLS

1 Delay locked loop device
2 Delay device
3 Delay element
4 Control device having a phase detector
5 Input connection
6 Output connection
2-A First circuit part
2-B Second circuit part
2-C Third circuit part
10 Delay chain
1-1 to 1-n Inverter stage
2-1 to 2-n Capacitance
3-1 to 3-n Transistor
K1, K2 Connecting node
IN Input connection
OT Output connection
Trcv Delay time
Tocd Delay time
clock Input clock signal
bclock Complementary input clock signal
clk Output clock signal
bclk Complementary output clock signal
A1, A2 Circuit block
B1, B2 Circuit block
C Circuit block
vn, vp Control signal
I Inverter stage
TG Transfer gate
G-1 to G-8 Gate
vint Supply voltage
gnd Reference voltage
clock/2 Clock signal which is at a reduced frequency
clock/2_{—}b Complementary clock signal which is at a reduced frequency
bclock/2 Complementary clock signal which is at a reduced frequency
bclock/2_{—}b Complementary clock signal which is complementary and is at a reduced frequency
out/2 Delayed clock signal which is at a reduced frequency
out/2_{—}b Delayed complementary clock signal which is at a reduced frequency
bout/2 Delayed complementary clock signal which is at a reduced frequency
bout/2_{—}b Delayed complementary clock signal which is complementary and is at a reduced frequency
Cp Capacitance
Is Controllable inverter stage
P0, P1 Signal path
δ Delay time
δA Delay time
δdll Delay time
δM Delay time
(1) to (4) Time
(1′) to (4′) Time

What is claimed is:

1. A delay locked loop device comprising:
an input connection that receives an input clock signal that is to be delayed;
an output connection that provides a delayed output clock signal;
a delay device comprising a controllable delay time, a first circuit part, a second circuit part that is connected downstream in a signal flow direction from the first circuit part, and a third circuit part that is connected downstream in a signal flow direction from the second circuit part, wherein the delay device is connected in series between the input connection and the output connection;
a control device that provides a control signal to the delay device, wherein the control signal is determined by a phase difference between the input clock signal and the delayed output clock signal;
wherein:
the first circuit part is configured to receive and reduce the frequency of the input clock signal so as to produce a clock signal at a reduced frequency to that of the input clock signal;
the second circuit part is configured to receive the clock signal at the reduced frequency and delay the clock signal at the reduced frequency by a controllable delay time so as to produce a clock signal at the reduced frequency and a delayed time to that of the input clock signal;
the third circuit part is configured to receive and reconstruct the clock signal at the reduced frequency and the delayed time such that the output clock signal is at the frequency of the input clock signal.

2. The delay locked loop device according to claim 1, wherein:
the input connection receives the input clock signal that is to be delayed and a complementary input clock signal that is complementary to the input clock signal;
the first circuit part receives and reduces the frequencies of the input clock signal and the complementary input clock signal so as to produce the clock signal at the reduced frequency and a complementary clock signal that is at a reduced frequency to that of the complementary input clock signal;
the second circuit part comprises first and second delay chains that forward modified clock signals to a third circuit part, wherein the first delay chain forwards the clock signal at the reduced frequency, the second delay chain forwards the complementary clock signal at the reduced frequency, and the signals being forwarded to the third circuit part are delayed by a controllable delay time; and
the third circuit part uses the delayed clock signal at the reduced frequency and the delayed complementary clock signal at the reduced frequency to generate the output clock signal.

3. The delay locked loop device according to claim 2, wherein the third circuit part generates the rising edges of the output clock signal from the rising and falling edges of the delayed clock signal at the reduced frequency and generates the falling edges of the output clock signal from the rising and falling edges of the delayed complementary clock signal at the reduced frequency.

4. The delay locked loop device according to claim 2, wherein the second circuit part delays the signals such that the delay time is approximately the same for the clock signal at the reduced frequency and the complementary clock signal at the reduced frequency.

5. The delay locked loop device according to claim 3, wherein the second circuit part delays the signals such that the delay time is approximately the same for the clock signal at the reduced frequency and the complementary clock signal at the reduced frequency.

6. The delay locked loop device according to claim 4, wherein the second circuit part delays the signals such that the rising and falling edges of the clock signal at the reduced frequency and of the complementary clock signal at the reduced frequency are delayed to approximately the same extent.

7. The delay locked loop device according to claim 5, wherein the second circuit part delays the signals such that the rising and falling edges of the clock signal at the reduced frequency and of the complementary clock signal at the reduced frequency are delayed to approximately the same extent.

8. The delay locked loop device according to claim 1, wherein:
the input connection receives the input clock signal that is to be delayed and an input clock signal that is complementary to the input clock signal;
the first circuit part receives the input clock signal and generates the clock signal at the reduced frequency and a clock signal which is at a reduced frequency and is complementary to the input clock signal, and the first circuit part receives the complementary input clock signal and generates a complementary clock signal that at a reduced frequency and a clock signal that is at a reduced frequency and is complementary to the complementary input clock signal;
the second circuit part comprises four delay chains, wherein a first delay chain forwards the clock signal at the reduced frequency, a second delay chain forwards the clock signal at the reduced frequency and which is complementary to the input clock signal, a third delay chain forwards the complementary clock signal at the reduced frequency, and a fourth delay chain forwards the clock signal at the reduced frequency and which is complementary to the complementary input clock signal, and each of the signals are forwarded to the third circuit part such that each of the signals has been delayed by a controllable delay time; and
the third circuit part uses the delayed clock signal at the reduced frequency, the delayed clock signal at the reduced frequency and which is complementary to the input clock signal, the delayed complementary clock signal at the reduced frequency and the delayed clock signal at the reduced frequency and which is complementary to the complementary input signal to generate the output clock signal.

9. The delay locked loop device according to claim 8, wherein:
the third circuit part generates the rising edges of the output clock signal from the rising edges of the delayed clock signal at the reduced frequency and the rising edges of the delayed clock signal at the reduced frequency and which is complementary to the input clock signal; and
the third circuit part generates the falling edges of the output clock signal from the rising edges of the delayed complementary clock signal at the reduced frequency and the rising edges of the delayed clock signal at the reduced frequency and which is complementary to the complementary input clock signal.

10. The delay locked loop device according to claim 1, wherein the second circuit part comprises a delay chain including inverter stages that are connected in series and a respective capacitance being connected to respective connecting nodes between the inverter stages.

11. The delay locked loop device according to claim 10, wherein a first connection of the respective capacitance is connected to the respective connecting node via a controllable transistor that is responsive to the control signal from the control device.

12. The delay locked loop device according to claim 10, wherein a first connection of the respective capacitance is connected to the respective connecting node, and a second connection of the respective capacitance is connected to a potential connection, wherein a potential applied to the potential connection is responsive to the control signal from the control device.
